(19) United States
(12) Patent Application Publication
(10) Pub. No.: US 2026/0189186 A1
(43) Pub. Date: Jul. 2, 2026

(54) AMPLIFIER DEVICE

(71) Applicant: RichWave Technology Corp., Taipei (TW)

(72) Inventors: Tien-Yun Peng, Taipei (TW); Chih-Sheng Chen, Taipei (TW)

(73) Assignee: RichWave Technology Corp., Taipei (TW)

(21) Appl. No.: 19/048,986

(22) Filed: Feb. 10, 2025

(30) Foreign Application Priority Data
Jan. 2, 2025 (TW) 114100054

(51) Int. Cl. H03F 1/02

(52) U.S. Cl. CPC H03F 1/0211

(57) ABSTRACT

An amplifier device, including an inductor, a capacitor, an amplifier, a drive circuit, and a bias circuit, is provided. The inductor and the capacitor are connected in series between a bias point and a first reference voltage terminal. The amplifier is coupled to the bias point to receive a bias signal. The drive circuit receives a start signal and provides a charging signal. The bias circuit is coupled to the bias point and the drive circuit. In a first mode, the start signal has a first level, and the bias circuit provides the bias signal at the bias point according to a bias reference signal and the charging signal. In a second mode, the start signal has a second level, and the bias circuit provides the bias signal at the bias point according to the bias reference signal.

### CROSS-REFERENCE TO RELATED APPLICATION

This application claims the priority benefit of Taiwan application Ser. No. 114100054, filed on Jan. 2, 2025. The entirety of the above-mentioned patent application is hereby incorporated by reference herein and made a part of this specification.

### BACKGROUND

### Technical Field

The disclosure relates to a communication circuit design technology, and particularly relates to an amplifier device.

### Description of Related Art

Amplifiers are often used to amplify signals in wired or wireless communication technology. Since there are requirements for signal transmission speed in the current communication technology, the signal processing frequency has increased, thus the noise at the input terminal or bias terminal of the amplifier is increased. In order to reduce noise and avoid affecting the overall signal linearity of the circuit, a large-value capacitor is added to the input terminal or bias terminal of the amplifier.

However, the large-value capacitor may prolong the time for the amplifier operating in the transient state, which causes the amplifier to have a longer transient response time before settling into a steady state. Therefore, how to maintain the amplifier's signal linearity and a short transient response time is one of the directions of technical research.

### SUMMARY

An amplifier device of the disclosure includes an inductor, a capacitor, an amplifier, a drive circuit, and a bias circuit. The capacitor and the inductor are connected in series. The inductor and the capacitor are connected in series between a bias point and a first reference voltage terminal. The amplifier is coupled to the bias point to receive a bias signal. The drive circuit receives a start signal and provides a charging signal. The bias circuit is coupled to the bias point and the drive circuit. In a first mode, the start signal has a first level, and the bias circuit provides the bias signal at the bias point according to a bias reference signal and the charging signal. In a second mode, the start signal has a second level, and the bias circuit provides the bias signal at the bias point according to the bias reference signal.

### BRIEF DESCRIPTION OF THE DRAWINGS

FIG. 1 is a block diagram of an amplifier circuit according to an embodiment of the disclosure.

FIG. 2 is a circuit diagram of an amplifier circuit according to a first embodiment of the disclosure.

FIG. 3 is a detailed circuit diagram of a low dropout voltage regulator according to an embodiment of the disclosure.

FIG. 4 is a waveform diagram of a reference voltage, a start signal, and a charging signal according to an embodiment of the disclosure.

FIG. 5 is a circuit diagram of a compensation circuit according to an embodiment of the disclosure.

### DESCRIPTION OF THE EMBODIMENTS

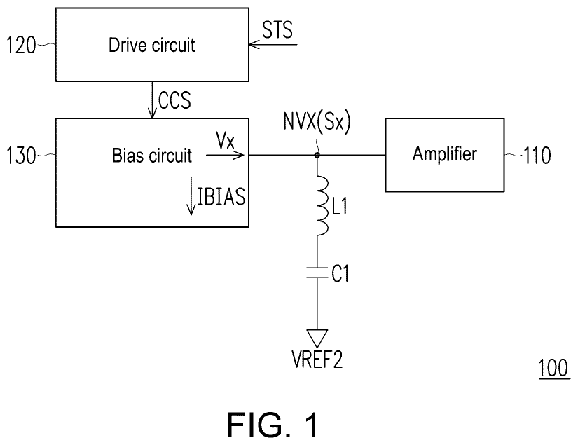

FIG. 1 is a block diagram of an amplifier circuit 100 according to an embodiment of the disclosure. The amplifier circuit 100 includes an inductor L1, a capacitor C1, an amplifier 110, a drive circuit 120, and a bias circuit 130. The capacitor C1 and the inductor L1 are connected in series. The inductor L1 and the capacitor C1 are connected in series between a bias point NVX and a reference voltage terminal VREF2 (for example, the ground terminal). The reference voltage terminal VREF2 has a reference voltage (for example, the ground voltage). The capacitor C1 in the embodiment has a capacitance value of approximately 10 n to 50 nF.

The amplifier 110 is coupled to the bias point NVX to receive a bias signal Sx at the bias point NVX. The drive circuit 120 receives a start signal STS and provides a charging signal CCS. The bias circuit 130 is coupled to the bias point NVX and the drive circuit 120. The bias circuit 130 provides the bias signal Sx at the bias point NVX according to a bias reference signal (for example, a bias current IBIAS is taken as an example in the embodiment) and selectively according to the charging signal CCS.

In an embodiment, the activation or disabling of the drive circuit 120 is controlled by the start signal STS. For example, in a first mode, the start signal STS has a first level (for example, logic “1”). The drive circuit 120 is activated in response to the start signal STS having the first level, and provides the charging signal CCS to the bias circuit 130. The bias circuit 130 provides the bias signal Sx at the bias point NVX according to the bias reference signal (for example, the bias current IBIAS) and the charging signal CCS. On the other hand, in a second mode, the start signal STS has a second level (for example, logic “0”). The drive circuit 120 is disabled in response to the start signal STS having the second level, and does not provide the charging signal CCS to the bias circuit 130. The bias circuit 130 provides the bias signal Sx at the bias point NVX according to the bias reference signal (for example, the bias current IBIAS). In the embodiment, the bias signal Sx in the first mode is greater than the bias signal Sx in the second mode because the bias signal Sx in the first mode is also affected by the charging signal CCS, resulting in an increase in its current/voltage. In the second mode, the bias circuit 130 may include at least the following embodiments according to the bias reference signal, as long as the bias signal Sx in the first mode may be greater than the bias signal Sx in the second mode: in an embodiment, in the second mode, the bias circuit 130 provides the bias signal Sx at the bias point NVX only according to the bias reference signal (for example, the bias current IBIAS). In another embodiment, in the second mode, the bias circuit 130 provides the bias signal Sx at the bias point NVX at least according to the bias reference signal and stops to provide the bias signal Sx based on the charging signal CCS. In yet another embodiment, in the second mode, the bias circuit 130 provides the bias signal Sx at the bias point NVX according to the bias reference signal and the charging signal CCS which is smaller than the charging signal CCS in the first mode.

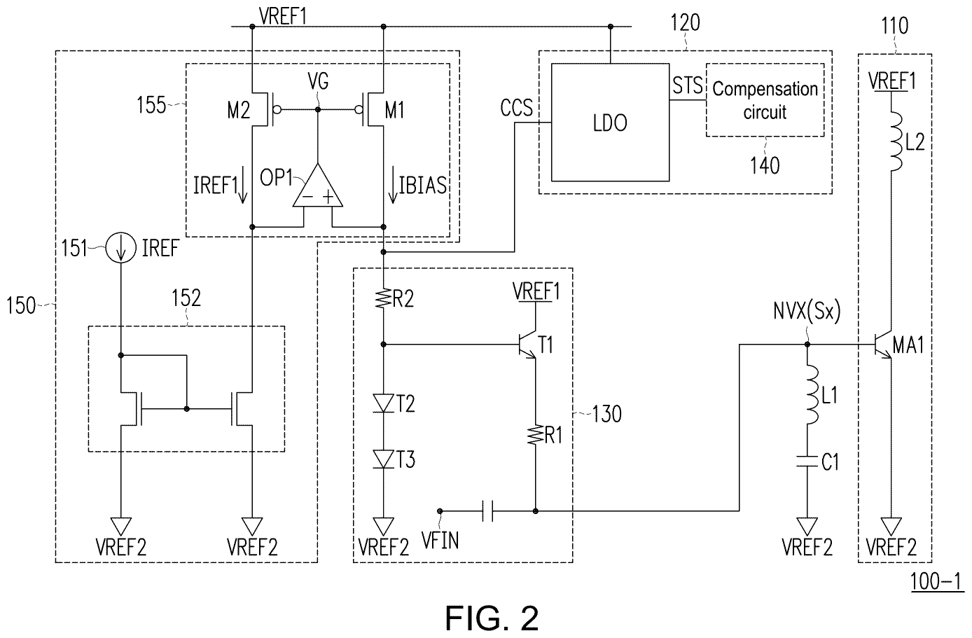

FIG. 2 is a circuit diagram of an amplifier circuit 100-1 according to a first embodiment of the disclosure. The amplifier circuit 100-1 depicted in FIG. 2 is an implementation of the amplifier circuit 100 depicted in FIG. 1. FIG. 2 mainly shows the detailed circuit structure of the amplifier 110, the drive circuit 120, and the bias circuit 130. The amplifier 110 mainly includes a transistor MA1 used as an amplifier. One terminal of the transistor MA1 (for example, the collector terminal) may be coupled to a reference voltage terminal VREF1 through an inductor L2 to receive the reference voltage (for example, a reference voltage VREF), and the other terminal (for example, the emitter terminal) of the transistor MA1 is coupled to the reference voltage terminal VREF2 (for example, the ground or 0V). A control terminal (for example, the base terminal) of the transistor MA1 is coupled to a bias terminal NVX. In an embodiment, a terminal of the transistor MA1 may be coupled to the circuit operating voltage terminal through the inductor L2 to receive the circuit operating voltage (for example, VCC or a third reference voltage). Specifically, in the embodiment, the voltage of the reference voltage terminal VREF1 may be, for example, a circuit operating voltage, a system voltage, or other reference voltages different from the reference voltage terminal VREF2. The voltage value thereof remains unchanged at least for a period of time (for example, remains unchanged in the first mode and/or the second mode), or remains unchanged continuously.

The drive circuit 120 mainly includes a low dropout voltage regulator LDO. The low dropout voltage regulator LDO receives the start signal STS to generate the charging signal CCS. The drive circuit 120 depicted in FIG. 2 also includes a compensation circuit 140. The compensation circuit 140 is configured to generate the start signal STS. The start signal STS may be related to at least one of the reference voltage VREF (for example, a system voltage VDD), the temperature, and the PN junction cross-voltage.

The amplifier circuit 100-1 depicted in FIG. 2 also includes a current source circuit 150 that provides the bias current IBIAS to the bias circuit 130. In detail, the current source circuit 150 includes a current source 151, a current mirror circuit 152, and a current mirror circuit 155. One terminal of the current mirror circuit 152 receives a current IREF provided by the current source 151, and the other terminal of the current mirror circuit 152 provides a current IREF1 to a first branch of the current mirror circuit 155. The current mirror circuit 155 includes an operational amplifier OP1, a transistor M1 through which the bias current IBIAS flows, and a transistor M2 through which the current IREF1 flows. First terminals (for example, the source terminals) of the transistor M1 and the transistor M2 are coupled to the reference voltage terminal VREF1 to receive the reference voltage (for example, the reference voltage VREF), and a second terminal (for example, the drain terminal) of the transistor M2 provides the bias current IBIAS to the bias circuit 130. A non-inverting input terminal of the operational amplifier OP1 is coupled to a second terminal (for example, the drain terminal) of the transistor M1. An inverting input terminal of the operational amplifier OP1 is coupled to the second terminal (for example, the drain terminal) of the transistor M2. An output terminal of the operational amplifier OP1 is coupled to control terminals (for example, the gate terminals) of the transistors M1 and M2. By designing the transistor sizes of the transistors M1 and M2, the current value magnification of the bias current IBIAS and the current IREF1 may be adjusted. In an embodiment, the current source circuit 150 may not include the operational amplifier OP1.

The bias circuit 130 includes a transistor T1. A control terminal (for example, the base terminal) of the transistor T1 is coupled to the drive circuit 120 through a resistor R2 to receive the charging signal CSS. The control terminal of the transistor T1 and a first terminal of a diode T2 may be coupled to the reference voltage terminal VREF1 through the resistor R2 and the transistor M1 to receive the reference voltage (for example, the reference voltage VREF). One terminal (for example, the collector terminal) of the transistor T1 is coupled to the reference voltage terminal VREF1 to receive the reference voltage (for example, the reference voltage VREF, the system voltage VDD or the second reference voltage). The other terminal of the transistor T1 (for example, the emitter terminal) is coupled to the bias terminal NVX through a resistor R1. The bias terminal NVX may also be coupled to a signal input terminal VFIN through a capacitor. The amplifier 110 receives the radio frequency signal from the signal input terminal VFIN and amplifies the radio frequency signal. The inductor L1 and the capacitor C1 form a resonant circuit to provide lower impedance to the baseband signal and higher impedance to the radio frequency signal. The charging signal CCS charges the capacitor C1 through the transistor T1. In an embodiment, a terminal of the transistor T1 of the bias circuit 130 is coupled to the reference voltage terminal VREF1 to receive the reference voltage (for example, the reference voltage VREF), and a terminal (for example, the collector terminal) of the transistor MA1 of the amplifier 110 may be coupled to the reference voltage terminal VREF1 through the inductor L2 to receive the reference voltage (for example, the reference voltage VREF). In an embodiment, the terminal of the transistor T1 of the bias circuit 130 is coupled to the reference voltage terminal VREF1 to receive the reference voltage (for example, the reference voltage VREF), and the terminal (for example, the collector terminal) of the transistor MA1 of the amplifier 110 may be coupled to the circuit operating voltage terminal through the inductor L2 to receive the circuit operating voltage (for example, VCC).

The bias circuit 130 also includes diodes T2 and T3. The diodes T2 and T3 in the embodiment may be implemented by transistors (for example, bipolar transistor or field effect transistor (FET)). A first terminal (for example, the anode terminal) of the diode T2 is coupled to the control terminal of the transistor T1 and is coupled to the second terminal of the transistor M1 through resistor R2. A second terminal (for example, the cathode terminal) of the diode T2 is coupled to a first terminal (for example, the anode terminal) of the diode T3. A second terminal (for example, the cathode terminal) of the diode T3 is coupled to the reference voltage terminal VREF2 (for example, the ground terminal). The drive circuit 120 of the embodiment may be implemented using a silicon-on-insulator (SOI) process. The bias circuit 130 and the amplifier 110 may be implemented using a gallium arsenide (GaAs) process.

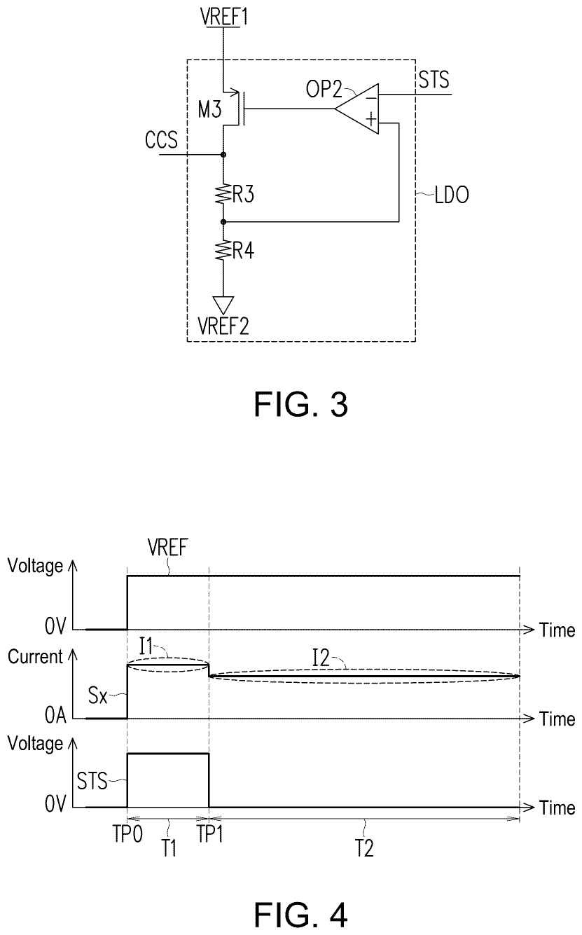

FIG. 3 is a detailed circuit diagram of a low dropout voltage regulator LDO according to an embodiment of the disclosure. The low dropout voltage regulator LDO includes an operational amplifier OP2, a transistor M3, and resistors R3 and R4. An inverting input terminal of the operational amplifier OP2 receives the start signal STS. A non-inverting input terminal of the operational amplifier OP2 is coupled to a terminal of the resistor R3 and a terminal of the resistor R4. An output terminal of the operational amplifier OP2 is coupled to a control terminal (for example, the gate terminal) of the transistor M3. A first terminal (for example, the source terminal) of the transistor M3 is coupled to the reference voltage terminal VREF1 (for example, the reference voltage VREF). The other terminal of the resistor R4 is coupled to the reference voltage terminal VREF2 (for example, the ground terminal). A second terminal of the transistor M3 is coupled to the other terminal of the resistor R3 and serves as the output terminal of the low dropout voltage regulator LDO to provide the charging signal CCS. The other terminal of the transistor M3 is coupled to another reference voltage terminal VREF1 (for example, the reference voltage VREF).

For example, FIG. 4 is a waveform diagram of the reference voltage VREF, the bias signal Sx and the start signal STS according to an embodiment of the disclosure. Referring to FIG. 4, the start signal STS may be a pulse signal. The start signal STS has a transition point TP1. The start signal STS has a first level (for example, logic “1”) in a first period T1 before the transition point TP1, and the start signal STS has a second level (for example, logic “0”) in a second period TP2 after the transition point TP1. The bias signal Sx (for example, a mark I1) in the first period T1 before the transition point TP1 (that is, the period between a time point TP0 and the transition point TP1) is greater than the bias signal Sx (for example, a marked I2) in the second period TP2 after the transition point TP1. The first period T1 may correspond to the first mode, and the second period TP2 may correspond to the second mode. In an embodiment, the reference voltage VREF (for example, the system voltage VDD) may maintain a high level (for example, the system voltage VDD) during both the first period T1 and the second period.

In another embodiment of the disclosure, the drive circuit 120 may not be disabled, but may provide different types of charging signals CCS to the bias circuit 130. For example, the charging signal CCS of the start signal STS in the first period T1 (that is, the period between the time point TP0 and the transition point TP1) before the transition point TP1 is greater than the charging signal CCS of the start signal STS in the second period TP2 after the transition point TP1, and neither the first period T1 nor the second period T2 is equal to 0.

The start signal STS may be a signal generated based on a corresponding parameter detection circuit. For example, the start signal STS is related to at least one of the reference voltage VREF (for example, the system voltage VDD or the second reference voltage), the temperature, and the PN junction cross-voltage. For example, the start signal STS may be based on one of the following: the system voltage (for example, the system voltage VDD), the temperature signal provided by the ambient temperature sensing circuit, the temperature compensation signal provided by the temperature compensation circuit, the temperature-drift-free signal provided by the temperature-drift-free voltage generator, the signal generated based on the PN junction cross-voltage in the semiconductor manufacturing process, or a combination thereof. The PN junction cross-voltage may be related to the process variation. The charging signal CCS is generated by the start signal STS, so the charging signal CCS is also related to at least one of the reference voltage VREF (for example, VDD), the temperature, and the process variation. Those who apply the embodiment may adjust the reference source (for example, the reference voltage VREF, the ambient temperature detection signal, the PN junction cross-voltage, temperature-drift-free signal, etc.) related to the start signal STS according to their requirements. The charging signal CCS in the embodiment is related to the reference voltage VREF as an example.

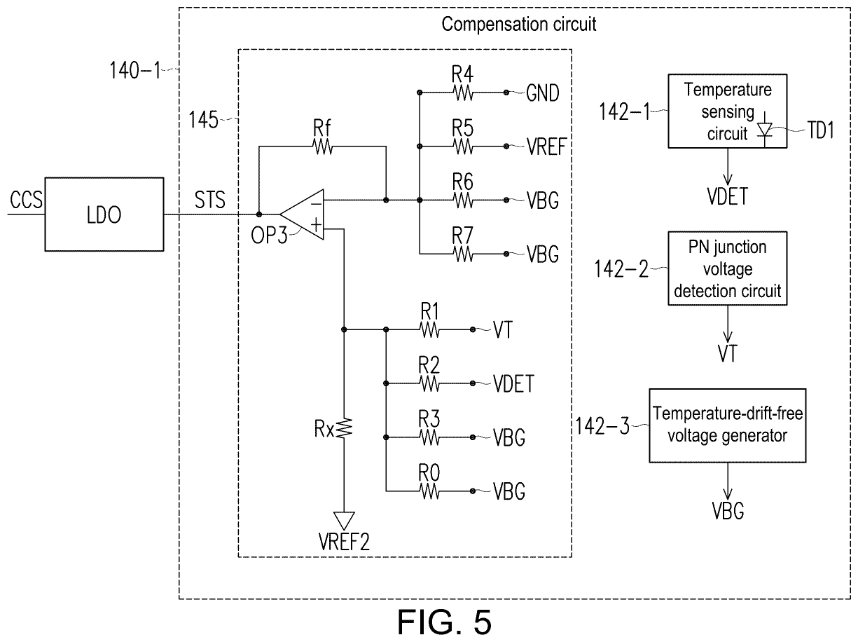

FIG. 5 is a circuit diagram of a compensation circuit 140-1 according to an embodiment of the disclosure. The compensation circuit 140-1 depicted in FIG. 5 is one implementation of the compensation circuit 140 in the amplifier circuit 100-1 depicted in FIG. 3. The compensation circuit 140-1 depicted in FIG. 5 includes at least one reference signal source circuit (for example, a temperature sensing circuit 142-1, a PN junction voltage detection circuit 142-2, a temperature-drift-free voltage generator 142-3, etc.) and an adder circuit 145. The temperature sensing circuit 142-1 may generate a temperature sensing voltage VDET according to a sensing diode TD1. The PN junction voltage detection circuit 142-2 may generate a detection voltage VT based on the PN junction voltage to obtain the process variation. The sensing diode TD1 of the embodiment may be made of gallium arsenide (GaAs). The temperature-drift-free voltage generator 142-3 may generate a temperature-drift-free voltage VBG.

The adder circuit 145 of the embodiment may operate these reference signals (for example, the temperature sensing voltage VDET, the detection voltage VT, the temperature-drift-free voltage VBG, and the reference voltage VREF) to generate the start signal STS. For example, the adder circuit 145 depicted in FIG. 5 includes an operational amplifier OP3, resistors R0 to R7, a resistor Rf, and a resistor Rx. A first input terminal (for example, the non-inverting input terminal) of the operational amplifier OP3 receives the temperature-drift-free voltage VBG through the resistor R0, the detection voltage VT through the resistor R1, the temperature sensing voltage VDET through the resistor R2, and the temperature-drift-free voltage VBG through the resistor R3, and is coupled to the reference voltage terminal (for example, the ground terminal) through the resistor Rx. A second input terminal (for example, the inverting input terminal) of the operational amplifier OP3 receives a ground signal GND through the resistor R4, the reference voltage VREF through the resistor R5, the temperature-drift-free voltage VBG through the resistor R6, the temperature-drift-free voltage VBG through the resistor R7, and is coupled to the output terminal of the operational amplifier OP1 through the resistor Rf. The resistance value of the resistor R4 is equal to the resistance value of the resistor R0, the resistance value of the resistor R5 is equal to the resistance value of the resistor R1, the resistance value of the resistor R6 is equal to the resistance value of the resistor R2, and the resistance value of the resistor R7 is equal to the resistance value of the resistor R3.

In the embodiment, the resistance values of resistor Rf and resistor R0 may be configured to have a multiple K0 (for example, K0=Rf/R0), the resistance values of resistor Rf and resistor R1 may be configured to have a multiple K1 (for example, K1=Rf/R1), the resistance values of resistor Rf and resistor R2 may be configured to have a multiple K2 (for example, K2=Rf/R2), and the resistance values of resistor Rf and resistor R3 may be configured to have a multiple K3 (for example, K3=Rf/R3). Therefore, the start signal STS of the embodiment will generate the detection voltage VT and multiples K0 to K3 according to the temperature-drift-free voltage VBG, the reference voltage VREF, the temperature sensing voltage VDET, and the PN junction voltage, and the bias signal Sx is generated (for example, Sx=K0×VBG+K1×(VBG-VREF)+K2×(VDET-VBG)+K3×(VT-VBG)). The low dropout voltage regulator LDO receives the start signal STS to generate the charging signal CCS, and the bias circuit 130 provides the bias signal Sx at the bias point NVX according to the bias reference signal (for example, the bias current IBIAS) and the charging signal CCS.

In an embodiment, the compensation circuit 140-1 may only include a temperature-drift-free voltage generator 142-3 and an adder. The adder is coupled to the reference voltage terminal VREF1 to receive the reference voltage VREF, and is coupled to the temperature-drift-free voltage generator 142-3 to receive the temperature-drift-free voltage VBG, so as to change the start signal CCS in response to changes in the reference voltage VREF. Specifically, in the embodiment, the reference voltage VREF (for example, the system voltage VDD or the second reference voltage) may have a variation range in response to different operating states. In an embodiment, therefore, when the reference voltage VREF is low, the bias signal Sx provided by the bias circuit 130 has a weak driving capability, so the voltage of the start signal STS may be increased to enhance the charging signal CCS so as to maintain the driving capability of the bias signal Sx provided by the bias circuit 130. On the contrary, when the reference voltage VREF is high, the bias signal Sx provided by the bias circuit 130 has a strong driving capability, so the voltage of the start signal STS may be reduced to weaken the charging signal CCS so as to maintain the driving capability of the bias signal Sx provided by the bias circuit 130. Therefore, the charging signal CCS may be related to the reference voltage VERF on the reference voltage terminal. In an embodiment, the charging signal CCS may be inversely proportional to changes in the reference voltage VREF.

To sum up, the amplifier device of the embodiment of the disclosure uses the drive circuit 120 and related reference signals (for example, ambient temperature variability, system voltage variability, process variability, etc.) to generate the start signal STS. The driving signal correspondingly generates the charging signal CCS based on the start signal STS, and the bias circuit 130 instantly charges the capacitor located at the bias point of the amplifier based on the charging signal CCS, so as to reduce the transient response time of the amplifier device and make the operation of the amplifier circuit more stable.

What is claimed is:

1. An amplifier device, comprising:
an inductor;
a capacitor, connected in series with the inductor, wherein the inductor and the capacitor are connected in series between a bias point and a first reference voltage terminal;
an amplifier, coupled to the bias point to receive a bias signal;
a drive circuit, configured to receive a start signal and provide a charging signal; and
a bias circuit, coupled to the bias point and the drive circuit, wherein,
in a first mode, the start signal has a first level, and the bias circuit provides the bias signal at the bias point according to a bias reference signal and the charging signal, and
in a second mode, the start signal has a second level, and the bias circuit provides the bias signal at the bias point according to the bias reference signal.

2. The amplifier device according to claim 1, wherein in the second mode, the drive circuit is disabled.

3. The amplifier device according to claim 1, wherein the bias signal in the first mode is greater than the bias signal in the second mode.

4. The amplifier device according to claim 1, wherein the drive circuit comprises a low dropout voltage regulator, and the low dropout voltage regulator receives the start signal to generate the charging signal; or
wherein the drive circuit comprises a compensation circuit, the compensation circuit is configured to generate the start signal, and the start signal is related to at least one of a second reference voltage on a second reference voltage terminal, a temperature, and a PN junction cross-voltage.

5. The amplifier device according to claim 4, wherein the second reference voltage terminal is coupled to one or both of the bias circuit and the amplifier.

6. The amplifier device according to claim 1, wherein the bias circuit comprises a first transistor, the first transistor comprises a first terminal, a second terminal, and a control terminal, the first terminal is coupled to a second reference voltage terminal, the second terminal is coupled to the bias point, and the control terminal is coupled to the drive circuit to receive the charging signal.

7. The amplifier device according to claim 6, wherein the control terminal of the first transistor is coupled to the drive circuit through a resistor.

8. The amplifier device according to claim 7, wherein the bias circuit comprises a first diode and a second diode,
a first terminal of the first diode is coupled to the control terminal of the first transistor,
a second terminal of the first diode is coupled to a first terminal of the second diode,
a second terminal of the second diode is coupled to the first reference voltage terminal.

9. The amplifier device according to claim 6, wherein the charging signal charges the capacitor through the first transistor.

10. An amplifier device, comprising:
an inductor;
a capacitor, connected in series with the inductor, wherein the inductor and the capacitor are connected in series between a bias point and a first reference voltage terminal;
an amplifier, coupled to the bias point to receive a bias signal;
a drive circuit, configured to receive a start signal and provide a charging signal, wherein the charging signal is related to a second reference voltage on a second reference voltage terminal; and
a bias circuit, coupled to the bias point and the drive circuit, wherein the bias circuit provides the bias signal at the bias point according to a bias reference signal and the charging signal.

11. The amplifier device according to claim 10, wherein the start signal is a pulse signal.

12. The amplifier device according to claim 10, wherein the start signal has a transition point, and the charging signal in a first period before the transition point is greater than the charging signal in a second period after the transition point.

13. The amplifier device according to claim 10, wherein the drive circuit comprises a compensation circuit, the compensation circuit is configured to generate the charging signal, and the charging signal is related to a temperature or a PN junction cross-voltage.

14. The amplifier device according to claim 10, wherein the second reference voltage terminal is coupled to one or both of the bias circuit and the amplifier.

15. The amplifier device according to claim 10, wherein the bias circuit comprises a first transistor, the first transistor comprises a first terminal, a second terminal, and a control terminal, the first terminal is coupled to the second reference voltage terminal, the second terminal is coupled to the bias point, and the control terminal is coupled to the drive circuit to receive the charging signal.

16. The amplifier device according to claim 15, wherein the control terminal of the first transistor is coupled to the drive circuit through a resistor.

17. The amplifier device according to claim 16, wherein the bias circuit comprises a first diode and a second diode,
a first terminal of the first diode is coupled to the control terminal of the first transistor,
a second terminal of the first diode is coupled to a first terminal of the second diode,
a second terminal of the second diode is coupled to the first reference voltage terminal.

18. The amplifier device according to claim 15, wherein the charging signal charges the capacitor through the first transistor.

19. The amplifier device according to claim 10, wherein the drive circuit is implemented using a silicon-on-insulator (SOI) process, and the bias circuit and the amplifier are implemented using a gallium arsenide (GaAs) process.

20. The amplifier device according to claim 10, wherein the amplifier receives a radio frequency signal and amplifies the radio frequency signal, and the inductor and the capacitor form a resonant circuit and provide an impedance to a baseband signal.
